(19) United States
(12) Patent Application Publication
(10) Pub. No.: US 2005/0063440 A1
(43) Pub. Date: Mar. 24, 2005

(54) Epitaxial mode-confined vertical cavity surface emitting laser (VCSEL) and method of manufacturing same

(76) Inventor: Dennis G. Deppe, Austin, TX (US)

Correspondence Address: MORGAN, LEWIS & BOCKIUS, LLP., 2 PALO ALTO SQUARE, 3000 EL CAMINO REAL, PALO ALTO, CA, 94306, US

(21) Appl. No.: 10/943,617

(22) Filed: Sep. 17, 2004

Related U.S. Application Data
(60) Provisional application No. 60/504,299, filed on Sep. 18, 2003.

(51) Int. Cl. H01S 5/00

(52) U.S. Cl. 372/50; 372/99; 372/19

(57) ABSTRACT

A Vertical Cavity Surface Emitting Laser (VCSEL) includes an intracavity epitaxial layer configured to include a shallow mesa that alters the optical mode of the vertical cavity to laterally confine the optical mode in an otherwise planar epitaxial cavity. The VCSEL has optical confinement and current confinement within nearly the same active area and thus can operate with low threshold current, high efficiency, or high speed. In some embodiments, a mode confining region (i.e., mesa) is defined using a lithography process. This lithographic process eliminates external process variations such as material composition or thickness variation from influencing the mode confining region's size. The result is a highly uniform structure across a semiconductor wafer and from wafer to wafer. In some embodiments, the optical confinement and current confinement regions are self-aligned because the same manufacturing steps are used to form both. In other embodiments, the optical mode area is substantially different from the current injection area of the active material, but the current confinement area and the optical mode area are concentric or nearly concentric.

### RELATED APPLICATION

This application claims the benefit of priority from U.S. provisional application No. 60/504,299, filed Sep. 18, 2003, which provisional application is incorporated by reference herein in its entirety.

### TECHNICAL FIELD

This invention relates generally to solid-state optoelectronics devices, and more particularly relates to semiconductor vertical cavity surface emitting lasers (VCSELs).

### BACKGROUND

A vertical cavity surface emitting laser (VCSEL) can be formed from epitaxial semiconductor mirrors to create a very compact, low optical loss, all-semiconductor microcavity. The VCSEL has become an important laser device, because it can operate efficiently at low power levels with good beam characteristics, and is relatively easy to manufacture. VCSELs have applications in fiber optic transceivers, bar code scanners, compact disk storage, displays, solid state lighting, and others. VCSELs typically include a GaAs substrate on which AlₓG₁₋ₓAs/Al_{y}Ga_{1-y}As distributed Bragg reflecting (DBR) mirrors and active materials are grown using single crystal epitaxy. Other semiconductor or non-semiconductor substrates, such as InP or sapphire, can be used with different active materials to create VCSELs that operate over a wide range of wavelengths. These active materials may include: InGaN for ultraviolet and blue light emission; InGaAlP for visible light emission in a wavelength range between 600 nm and 700 nm; AlGaAs for light emission in a wavelength range between 700 nm and 850 nm; GaAs for emission in a wavelength range between 800 nm and 880 nm; InGaAs for light emission in a wavelength range between 900 nm and 1.2 μm range; and InGaNAs for light emission in a wavelength range between 1.1 μm and 1.6 μm. Combinations of these materials, including their nanostructures (e.g., quantum wires or quantum dots), can also be used to obtain even greater wavelength emission ranges for a given VCSEL substrate and mirror configuration. For example, planar layers of GaInNAs or GaAsSb, or nanostructures of InGaAs can be used to obtain 1.3 μm emission in AlGaAs-based VCSELs, and nanostructures of InGaNAs may be used to obtain even longer wavelengths extending beyond 1.6 μm.

VCSELs generally use conducting materials within the cavity to excite the optically active material. Generally, semiconductor materials conduct p- and n-type charges to inject holes and electrons into the active material to produce light emission. The conducting materials are placed between two mirrors to form a resonance cavity. The mirrors themselves may form the conducting materials. The two mirrors are made normal to the crystal surface to form the ends of the vertical cavity, and are generally made from DBRs which include alternating semiconductor layers with different refractive indices. The use of conducting mirrors can lead to a very compact, small volume light source that is readily excited by electrical current injection and operates with relatively high efficiency.

The VCSEL's vertical cavity defines the longitudinal optical mode spectrum of the device, and the conducting materials either placed between or in the mirrors define the longitudinal electrical current injection. A historical problem has been the lateral definition of both the optical mode and the electrical current injection region. To obtain the highest efficiency, it is desirable to laterally confine both the lateral optical mode and the current injection to nearly the same cross-sectional area. However, laterally confining the optical mode can also introduce optical loss, which is highly detrimental to the device performance. Some devices use reactive ion etching to form free-standing pillars that confine both the light and electrical current in the lateral direction. However, this type of device suffers increasing optical loss due to optical scattering at the surfaces of the pillar as the pillar diameter is reduced. It is also prone to surface degradation over time which causes poor reliability. Another fabrication approach uses proton or other impurity implantation to create defects outside a desired area so as to render the implanted material highly resistive, which restricts current injection to a small cross-sectional area. Some proton implanted VCSELs have high device reliability and are based on a simple fabrication process, but the optical loss is high due to the lack of an optical guide to confine the lasing mode. In addition, the optical mode can vary with a change in operating condition due to a temperature variation across the device that also changes the refractive index. Thus, these devices suffer from a relatively high threshold current and low modulation speed, and unstable lasing modes.

The lateral mode of a VCSEL can also be defined through an intracavity oxide aperture. The oxide aperture confines both the optical mode and the electrical current injection path to effectively the same cross-sectional area of the cavity with very low optical loss. The oxide-aperture is typically formed by selectively converting one or more semiconducting AlₓGa₁₋ₓAs layers to a native oxide using a steam oxidation technique. Because oxide-confined VCSELs can achieve low optical loss, they can have low threshold current, high efficiency, and high speed. For example, oxide confined VCSELs have threshold currents much lower than proton implanted VCSELs (less than one hundred microamps versus several milliamps for proton implanted VCSELs) and have obtained electrical to optical power conversion efficiencies of approximately fifty percent (50%).

Oxide-confined VCSELs have shown a substantial improvement in device characteristics over gain-guided proton implanted VCSELs. However, the need to form the oxide aperture by converting AlₓGa₁₋ₓAs to a native oxide is plagued with several manufacturing problems. The size of the oxide aperture is determined by the oxidation time. The oxidation time is sensitive to the ambient oxidation environment and the precise composition of AlₓGa₁₋ₓAs, both of which are difficult to control and can vary from wafer to wafer in a given fabrication process. In addition, the native oxide has a different thermal expansion coefficient from that of the surrounding semiconductor material of the VCSEL, and the strain that this difference induces inside the device can cause a substantial reliability problem and early device failure. Another limitation is that the native oxide process has thus far proven effective only for AlₓGa₁₋ₓAs, while other materials are desirable for VCSELs that operate at wavelengths that cannot be produced using GaAs/AlGaAs materials.

Some researchers have proposed to control the optical mode in a VCSEL by forming a recessed region within the vertical cavity, and covering at least part of this recessed region with electrodes. Very similar cavity designs were demonstrated earlier by others, but with electrodes placed outside the recessed region. The former design does not consider scattering loss that occurs from the recessed region. As discussed in detail later, these scattering losses can come from either the optical cavity partially covered with an electrode or the poor mode matching that comes from using a recessed region in an attempt to confine the optical mode. This optical loss can increase the VCSEL's threshold and decreases it efficiency. Other researchers have also proposed using recessed regions within the VCSEL to control the optical mode through diffraction loss of the beam, and to control the diffraction loss by using multiple closely spaced elements each with recessed regions. However, these researchers also do not consider how the optical mode is scattered by the recessed region, and temperature changes across the device can lead to mode instability due to its compensation of diffraction loss caused by the recessed regions. Their VCSEL devices show that the optical mode changes substantially with drive current.

Some researchers have proposed to control the optical mode of a VCSEL by combining a dielectric mirror with an epitaxial semiconductor cavity, so that the lower refractive index of the dielectric mirror deposited over the high refractive index of the semiconductor laterally confines the optical mode. In doing so they propose to use current confinement through an impurity implant into the semiconductor, and place electrodes on the semiconductor that are physically below the dielectric mirror. Examples of their choices for dielectric mirrors are MgF/ZnS, or other suitable materials that may be electron-beam deposited following epitaxial growth of the semiconductor. This VCSEL device has the drawback that the dielectric mirror material is different than the semiconductor used in the VCSEL, and can therefore add mechanical stress to the VCSEL and reduce its reliability. The implantation of the impurity must also be carefully controlled to enable electrodes to be placed on the same semiconductor crystal surface that receives the implantation. A similar VCSEL demonstrated by another research team, also uses nonepitaxial mirrors to complete an optical cavity. This VCSEL, however, can also suffer mechanical strain due to mismatch of its materials, and therefore reduced reliability.

Other approaches have also been proposed to make VCSELs in which the VCSEL is fully epitaxial but planar, and various types of impurities are introduced beneath the crystal surface. These approaches that are fully planar and all epitaxial generally do not provide the optical mode confinement to produce low threshold or high efficiency VCSELs needed for high speed modulation.

Thus, a need remains for a VCSEL that has very low optical loss in its mode confinement, low threshold current and high efficiency, and that can be fabricated using an optical cavity that is based on epitaxial semiconductor to eliminate or reduce the mechanical stress internal to the device and achieve high reliability. Furthermore, a need remains for such a VCSEL that is fabricated with a high reproducibility across a wafer and from wafer to wafer such as can be achieved using lithography, and that does not suffer lateral size variation due to external process parameters.

### SUMMARY

The disclosed embodiments of a VCSEL include an intracavity epitaxial layer configured to include a shallow mesa that alters the optical mode of the vertical cavity to laterally confine the optical mode in an otherwise planar epitaxial cavity. Therefore while the cavity may be nearly planar with respect to its crystal surfaces, the mesa leads to the creation of at least two distinct cavity types. Although mirrors of the VCSEL may be augmented by additional dielectric or metal layers, in some embodiments the mesa and mirror layers that cover the mesa are epitaxial. The VCSEL has optical confinement and current confinement within nearly the same active area and thus can operate with low threshold current, high efficiency, or high speed. The use of epitaxial DBRs eliminates strain in the semiconductor device, ensuring high reliability. The epitaxial DBRs also provide high reflectivity and low optical loss.

Some embodiments of the VCSEL provide a mode confining region (i.e., mesa) that is defined using a lithography process. This lithographic process eliminates external process variations such as material composition or thickness variation from influencing the mode confining region's size. The result is a highly uniform structure across a semiconductor wafer and from wafer to wafer. Another advantage of the VCSEL is that the optical confinement and current confinement regions are self-aligned because the same manufacturing steps are used to form both. In some embodiments, the optical mode area is substantially different from the current injection area of the active material, but the current confinement area and the optical mode area are concentric or nearly concentric.

### BRIEF DESCRIPTION OF DRAWINGS

FIG. 1A shows a schematic cross-section diagram of a partial epitaxial VCSEL cavity, with a shallow etched mesa formed on the crystal surface that will become the mode confined region.

FIG. 1B shows a schematic cross-section diagram of the DBR VCSEL after the second epitaxial growth that completes the formation of the two vertical cavities, the first vertical cavity formed at the location of the shallow etched mesa (now covered with a DBR) and the second vertical cavity formed outside the shallow etched mesa. The two epitaxial growth steps form the mode confined region. Electrodes are formed outside of the mode confining region so as to provide nearly uniform cavity characteristics both in the mode confined (mesa) and mode confining (adjacent to the mesa) regions.

FIG. 1C shows a schematic cross-section diagram of the DBR VCSEL after the second epitaxial growth that completes the formation of the two vertical cavities, the first vertical cavity formed at the location of the shallow etched mesa (now covered with a DBR) and the second vertical cavity formed outside the shallow etched mesa. Again, the two epitaxial growth steps form the mode confined region. In this example the electrodes formed over the mode confined region (mesa) are also formed over the mode confining region (adjacent to the mesa) so as to provide nearly uniform cavity characteristics in both regions.

FIG. 2 shows a schematic cross-sectional diagram of a VCSEL that uses an n⁺/p⁺ tunnel junction within the mesa to obtain high conductivity through the mesa. The n+/p+ tunnel junction layer is etched away outside the mesa to create low conductivity.

FIG. 3 shows the calculated plane wave cavity resonances for a cavity based on the design presented in FIG. 2. The reflectivity curve (a) shows the cavity response through cavity region 270 (first cavity through the mesa) as a solid curve, while curve (b) is through cavity region 280 (second cavity region outside the mesa) as a dashed curve. The differences in the cavity resonances confine the optical mode to the mesa for lateral mesa sizes that produce frequency shifts in the first cavity that are less than the frequency difference between the two cavity resonances.

FIG. 4 shows the experimentally measured current versus voltage characteristics for an AlGaAs all-epitaxial VCSEL either (a) through a 10 μm diameter mesa containing a tunnel junction, or (b) through a 100 μm diameter region that does not contain the mesa.

FIG. 5 shows an experimental light versus current curve measured for an AlGaAs VCSEL that uses a 10 μm diameter mesa and a tunnel junction to obtain high conductivity through the mesa. Lasing is obtained with a threshold current of 2.6 mA. The inset of FIG. 4 shows the lasing spectra measured from the all-epitaxial VCSEL, with lasing occurring at a wavelength of 965 nm, which is the wavelength corresponding to the cavity including the shallow mesa. The side lobes at 928 nm and 996 nm are due to the second cavity region formed outside the mesa. The side lobes do not lase but are excited due to current spreading.

FIG. 6 shows a schematic illustration of an embodiment in which an impurity implantation or diffusion is performed either on the upper cavity region, the lower cavity region, or both, prior to the second epitaxial growth. The impurity implant or diffusion is aligned to the shallow mesa to form a current blocking region outside the mesa.

FIG. 7 shows a schematic illustration of a VCSEL having a shallow mesa formed in the lower cavity region of the lower mirror. In this embodiment the mesa is formed below the active region on the substrate side of the VCSEL. Current blocking layers can be formed using an ion implantation, impurity diffusion, or tunnel junction, similar to the current blocking layers in embodiments that include a mesa formed in the upper mirror.

FIG. 8A shows a schematic illustration of an embodiment in which the etched mesa is formed above a tunnel junction so that the tunnel junction exists outside (below) the mesa.

FIG. 8B shows a schematic illustration of an embodiment in which impurity implantation or diffusion is used to convert the conductivity of the material above the tunnel junction and outside the etched mesa to the same conductivity type below the junction. The mesa and the region outside the mesa are epitaxially overgrown to form the cavity.

FIG. 8C shows a schematic illustration of an embodiment in which an intracavity electrical contact is used, and the injection current is confined to the mesa region through an impurity implant in a tunnel junction outside the mesa.

FIG. 9A shows a schematic illustration of the process steps used to form the mesa from a surface layer of AlGaAs for epitaxial regrowth just after ex-situ etching of the mesa. GaAs layers (or InGaAs) are used as protective layers to prevent oxidation of the AlGaAs crystal surfaces that will receive subsequent epitaxial regrowth.

FIG. 9B shows a schematic illustration of the epitaxial regrowth over the mesa. Prior to regrowth, the GaAs (or InGaAs) layers are thermally etched in-situ in the growth chamber using the thermal etch selectivity between GaAs (or InGaAs) and AlGaAs. The AlGaAs that receives the second epitaxial growth is then only exposed in the growth chamber.

FIG. 10A shows a schematic illustration of a mesa formed in the shape of a curved lens.

FIG. 10B shows a schematic illustration of the mesa after being covered with additional epitaxy.

FIG. 11 shows a schematic illustration of a 2-dimensional array of mesas arranged to form a weak photonic bandgap in the plane of the VCSEL. The 2-dimensional photonic crystal lattice can be designed to inhibit lateral propagation of the VCSEL's transverse modes, thus increasing the optical mode size for which the fundamental lowest order mode can be achieved.

### DETAILED DESCRIPTION OF EMBODIMENTS

The invention is described herein with reference to a series of examples of VCSELs that use an intracavity shallow mesa epitaxially grown into the semiconductor cavity. In one embodiment all electrodes for electrically contacting the VCSEL are separated from the optical mode so as to obtain very low optical loss by achieving nearly identical cavities between the mesa region and the region outside the mesa. In another embodiment the same electrode used to cover the cavity region containing the shallow mesa is also used in the adjacent region outside the mesa. The VCSEL's semiconductor DBRs may be augmented by additional dielectric or metal layers to increase reflectivity.

It has been found that semiconductor DBRs epitaxially grown over a shallow intracavity mesa produce high reflectivity in both the crystal region on top of the mesa and in the crystal region outside the mesa step. The shallow intracavity mesa confines the optical mode to the mesa-formed region. The mesa can be formed through patterned etching of the surface of a partially grown VCSEL cavity, with the optical confinement to the mesa, that is a first cavity, achieved by covering the mesa with a semiconductor DBR. The mode confinement to the mesa, a first cavity, is due to the influence of the cavity region formed outside the mesa, a second cavity, in converting the transverse part of the optical mode to nearly evanescent waves in the second cavity outside the mesa forming the first cavity. The resulting VCSEL is an all-epitaxial, very low loss mode confined VCSEL. The mode confinement is achieved by creating two cavities, the second cavity confining the optical mode to the first cavity.

It is a discovery used in the present embodiments that the vertical resonance of the first cavity region containing the mesa should be of a lower frequency relative to the second cavity region surrounding the mesa to provide low threshold, and that the longitudinal field profiles of the first and second cavities should be approximately the same. This precludes using a recessed region in the first cavity, as proposed by other researchers since a recessed region causes both diffraction loss and scattering loss out of the first cavity region into the second cavity region. This optical loss can increase the threshold, decrease the efficiency, and lead to mode instability due to thermal changes across the device. The same is true when the first cavity region is partially covered by electrodes since electrodes partially placed over the first cavity region that confines the optical mode can increase the optical scattering loss of the VCSEL.

In some embodiments, the shallow mesa presents a very small step height between the cavity region including the mesa and the cavity region outside the mesa. Further, the two distinct cavity regions are otherwise nearly identical in order to limit optical loss. For the lowest optical loss, this mesa height should be considerably less than a quarter of an effective optical wave in the semiconductor material. The small mesa height is needed because the shallow mesa causes two effects on the longitudinal electric field of the VCSEL. The first effect creates optical confinement in the mesa region forming the first cavity by limiting the transverse optical mode to evanescent waves in the second cavity region outside the mesa. Thus, a small mesa height eliminates diffraction loss in the confined optical mode. The second effect negatively influences VCSEL performance by causing optical scattering loss. The optical scattering loss is caused by the discontinuity in the cavity boundary along its longitudinal dimension due to the slight shift in layer thickness value, and that causes a different longitudinal field profile in the first cavity relative to the second cavity. While the reduction in diffraction loss is desirable to reduce the optical loss of the confined mode and occurs with even a very small step (e.g., a mesa height of less than 1/50 of an optical wave), the increase in scattering loss increases with increasing mesa step height and becomes significant even at ¼ of an optical wave in thickness. Very low optical loss is maintained by choosing a very small mesa height that eliminates diffraction loss and for which scattering loss is negligible. A larger mesa height may not further reduce diffraction loss and instead may only serve to increase scattering loss.

In some embodiments, the electrical current can be confined to the same optical mode confinement region of the shallow etched mesa. The electrical current is confined by a n⁺/p⁺ tunnel junction either in or near the shallow mesa and selectively patterned through either etching or introduction of impurities outside the mesa region. Alternate embodiments include implantation of impurity ions to form reverse biased p-n junctions or highly resistive layers outside the mesa so as to direct electrical current through the same cavity region formed by the shallow mesa. These alternate embodiments are useful when it is undesirable to use a reverse biased p⁺/n⁺ tunnel junction in defining the current injection path, for example, either because of excess resistance or absorption formed by the tunnel junction.

In some embodiments, the second epitaxial regrowth is performed directly on the semiconductor AlGaAs by in-situ thermal etching in the epitaxial growth chamber to remove sacrificial semiconductor layers of GaAs or InGaAs. Significant oxidation of the AlGaAs crystal during ex-situ processing needed to form the shallow etched mesa on the first epitaxial layer is thus avoided. Performing a subsequent epitaxial growth directly on AlGaAs is desirable to fabricate GaAs-based VCSELs that operate at wavelengths shorter than 0.87 μm. In such VCSELs, otherwise optically absorbing GaAs layers (needed to prevent oxidation of AlGaAs during ex-situ processing) may be removed from the VCSEL cavity to eliminate their optical absorption. Although not essential, since such GaAs layers may be placed at an antinode of the VCSEL's lasing mode, the removal of the GaAs layers can lead to very low optical loss.

In further embodiments, the shallow etched mesa is formed in the upper region of the lower semiconductor mirror, so that remaining layers of the lower mirror, active region, and upper mirror are formed in the second epitaxial regrowth over the mesa. Such a scheme is desirable to obtain greater optical confinement in the VCSEL active region, by creating a crystal step that extends into the active region and above. Alternatively, it may be desirable to perform the second epitaxial regrowth on a lower n-type mirror and confine the current by controlling the lateral conductivity in the lower mirror through implantation or impurity diffusion prior to growing the VCSEL active region.

In some embodiments, the etched mesas are arranged in a 2-dimensional microarray pattern so as to further control the lateral mode profile of the VCSEL through the formation of a weak 2-dimensional photonic crystal. In this type of micro-array, the epitaxial mesa sizes and spacings are reduced to limit the distance between neighboring mesas to less than the coherence length of the total lasing spectrum that might be achieved with a large single mesa. The epitaxial mesas are arranged on a 2-dimensional lattice that is chosen to create an energy gap that inhibits field propagation in the lateral direction of the cavity. In this manner higher order modes that depend on wave propagation in the lateral direction are suppressed, thereby favoring laser operation in the lowest order transverse mode. Large mode size, and therefore higher power, is achieved using such a micro-array.

### EXAMPLE 1

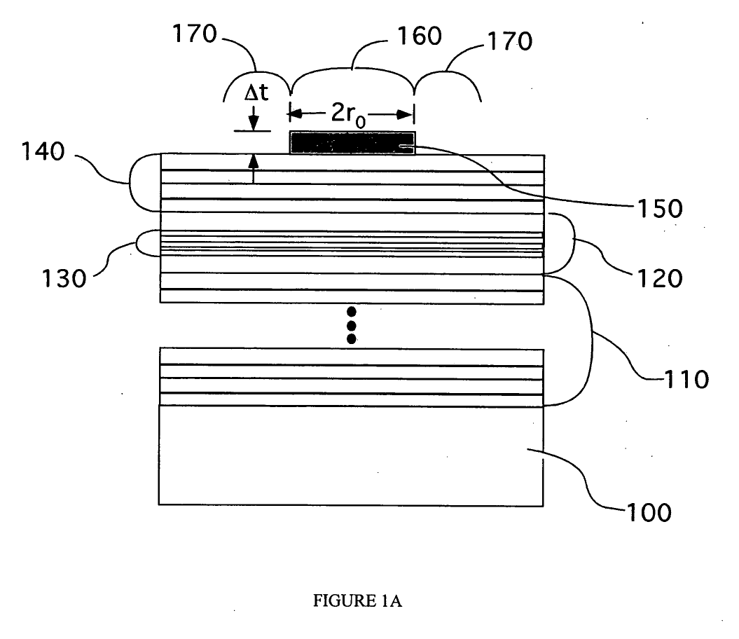

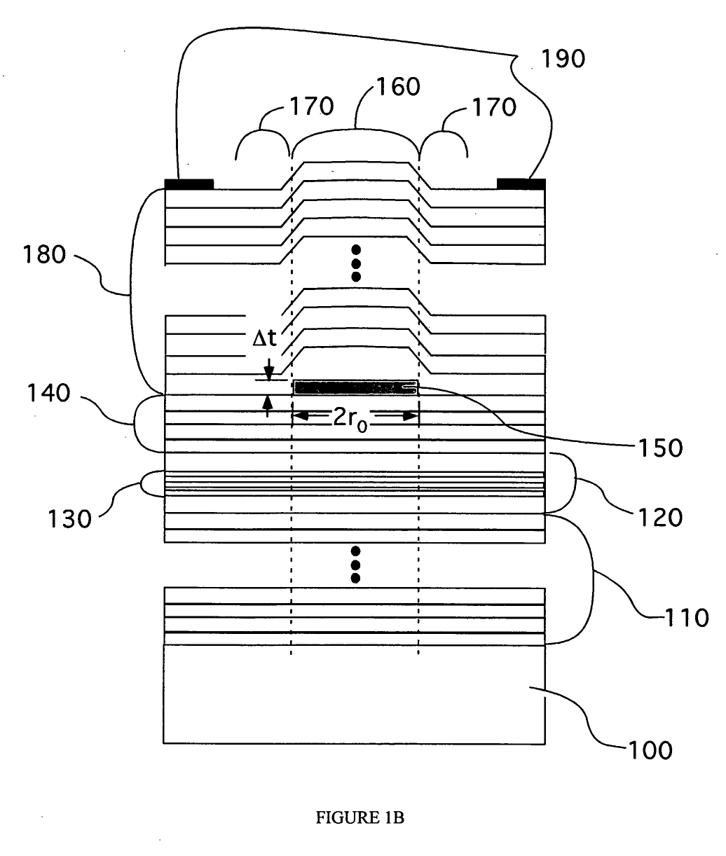

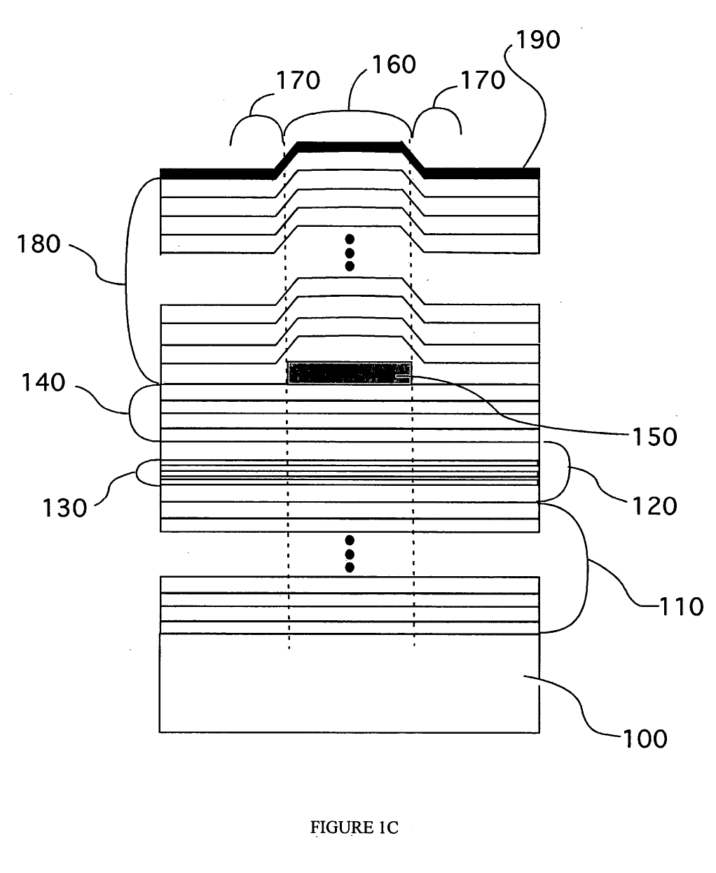

Reference is first made to FIG. 1A. FIG. 1A shows a schematic illustration of the heterostructure of a partial semiconductor VCSEL cavity. To form the partial cavity an epitaxial growth is performed on a substrate, layer 100, which may also contain various buffer layers used to prepare the crystal for growth of a lower DBR mirror layers 110. The lower DBR typically consists of semiconducting layers nominally lattice-matched to the substrate, but in some cases, for example for nitride semiconductors, the substrate may be sapphire or SiC. For AlGaAs VCSELs the substrate is generally GaAs. The lower DBR typically consists of alternating layers of semiconductors, for example AlₓGa₁₋ₓAs/Al_{y}Ga_{1-y}As, with alternating refractive indices in the layers to cause a constructive interference in the reflections of the DBR and yield high reflectivity at the desired wavelength. On this lower DBR layer 110 is grown an active region 120 consisting of a spacer layer and active layers 130 made of either bulk, quantum well, quantum wire, or quantum dot semiconducting materials. The spacer and active layer thicknesses that make up active region 120 are chosen to form a resonant cavity with the DBR mirrors. On this spacer are grown the first layers of the upper DBR, layers 140, which may consist of zero or more pairs of alternating mirror layers. On this upper part of the cavity a final layer of thickness Δt is formed and patterned, using lithography, for example, to form the shallow mesa layer 150. Although this mesa does not have to be cylindrically shaped, the numerical examples given below refer to a cylindrical mesa having a diameter of 2r₀.

Referring now to FIG. 1B, a subsequent epitaxial growth covers the shallow mesa 150 and forms two distinct but nearly identical cavity regions, a first cavity region 160 and a second cavity region 170. The two cavity regions 160 and 170 are formed by covering the semiconductor layers 140 and 150 with additional semiconductor layers 180 to complete or partially complete the upper DBR. The cavity region 180 is contacted with electrodes 190 that are placed well outside the mode confined in the first cavity region 160 by the second cavity region 170, so that regions 160 and 170 are nearly identical and therefore create nearly identical longitudinal field profiles except for that due to the small change in total layer thicknesses Δt due to mesa region 150. A feature of the completed VCSEL is that a resonance shift occurs for otherwise plane wave modes that could propagate through the first cavity region 160 that pass through the mesa 150, relative to the second cavity region that exists outside the mesa in region 170. As is known from VCSEL theory, the effect of such a resonance shift is to convert transversely propagating waves in the first cavity region 160 to nearly evanescent waves in the second cavity region 170. In the present embodiments, the shift in cavity resonance between the first cavity region 160 and the second cavity region 170 is obtained by physically shortening the epitaxial cavity length by Δt in region 170 by removal of the epitaxial layer used to form the mesa 150, while covering the mesa 150 in the first cavity region 160 and adjoining regions in the second cavity region 170 with additional epitaxial layers, including epitaxial mirrors. The minimum value Δt needed for the height of the mesa to achieve strong optical mode confinement depends on the lateral size of the optical mode that is desired to be confined as explained below. For lateral mode sizes much greater than an optical wavelength, for example with 2r₀≧10 wavelengths or so in diameter (considering the optical wavelength in the material) the mesa step height of layer 150 height may be on the order of 1/50 of an optical wavelength in the semiconductor material. Considering a GaAs/AlAs VCSEL designed to operate at 0.98 μm, a mesa height Δt of 66 Å in layer 150 placed in the first GaAs layer of the upper DBR will confine the optical mode with a beam waist of 2.5 μm. This small mode diameter is not possible in a conventional planar VCSEL (if layer 150 is reduced to zero thickness, so that Δt=0), designed for the same wavelength. For mesas with 2r₀>2 μm the optical mode will approximately grow to fill the mesa region until multimode operation is encountered, which is very similar to that expected for an index-confined VCSEL. Thus the VCSEL is a fully epitaxial, optically confined VCSEL that is nearly planar. In some cases it may also be desirable to augment the upper DBR of the second crystal growth step with a dielectric or conductor to increase the upper mirror reflectivity following the second epitaxial growth.

FIG. 1C shows a further embodiment in which the upper electrode 190 covers both cavity regions 160 and 170, and also serves as part of the reflector in these regions. For this type of VCSEL it is again important that the cavity region 160 be nearly identical to the cavity region 170, except for the shallow mesa layer 150, to avoid optical scattering loss as described below.

It is not necessary that mirror layers 110 and/or 140 and 180 be fully semiconductor DBRs. For example, mirror layers 180 may be augmented by additional dielectric layers to increase their reflectivity, while the mesa region and mirror layers that immediately contact the mesa are epitaxial. Or, in another embodiment, either DBR mirror regions 110, 140, or 180 may be formed using air-semiconductor reflectors. Such embodiments, having air-semiconductor DBRs, are particularly interesting because they provide an otherwise all epitaxial VCSEL without strain induced by intracavity oxides or other nonsemiconductor materials. In this type of VCSEL the actual materials composing the cavity are semiconductor, and the absence of materials, or with the inclusion of air inadvertently, become part of the mirrors. On the other hand, it is important that the cavity region inside the mesa (r≦r₀) closely match the cavity region outside the mesa (r>r₀).

Next, we consider the mesa layer 150, which is taken for example as cylindrically symmetric but more generally may have an arbitrary lateral shape. In the case that the mesa is cylindrical with coordinates (r,φ,z) with radius rₒ, a cavity region can be described inside the mesa region with r≦rₒ with a second cavity region outside the mesa region with r>rₒ. Because of the existence of the mesa layer 150, a longitudinal shift in the allowed wavevector components (in the z component) occurs between the cavity region with r≦rₒ and the cavity region with r>rₒ. Complete sets of eigenmodes can be defined in the cavity region with r≦rₒ and r>rₒ, and these are matched by Maxwell's equations at the boundary rₒ for all φ and z positions. In the case of a VCSEL our interest is in how an optical mode confined in the region with r≦rₒ couples to the modes of region r>rₒ. While the eigenmodes that are confined (or more accurately approximately confined due to some lateral optical loss) to region r≦rₒ have real wavevector components in the r or φ directions, these should be predominantly evanescent or imaginary in the r or φ directions for r>rₒ to achieve low optical loss. This can be achieved when the longitudinal mode distribution in the z direction for r≦rₒ nearly matches the longitudinal mode distribution in the z direction for r>rₒ, so that modes orthogonal in their z components for r≦rₒ are nearly orthogonal to those for r>rₒ as well.

To place the discussion in mathematical terms of mode orthogonality, we consider a cylindrically symmetric lowest order mode of the mesa region 160 as Eₘ_{ᵣ}_{,0,m}_{_{z}}(r≦rₒ,z), where mᵣ and m_{z} define the mode numbers in the r and z directions, and the mode outside the mesa as a sum over the complete set of modes m′ of the region r>rₒ as

$${\sum }_{{m}^{′}}^{} {c}_{{m}^{′}} {E}_{{m}^{′}} ( r > {r}_{o} , z ) .$$

Here we assume because of symmetry, that only the cylindrically symmetric modes in r>rₒ can couple to Eₘ_{ᵣ}_{,0,m}_{_{z}}(r≦rₒ,z). To determine how the mesa mode Eₘ_{ᵣ}_{,0,m}_{_{z}}(r≦rₒ,z) couples to the modes

$${\sum }_{{m}^{′}}^{} {c}_{{m}^{′}} {E}_{{m}^{′}} ( r > {r}_{o} , z )$$

we use the condition of strict orthogonality of the spatial electromagnetic modes in each region to determine the coefficients c_{m′}. The coefficients are determined by the overlap integral at the mesa layer 150 boundary, so that

$${c}_{{m}^{′}} = \frac{\int ⅆ z {E}_{{m}^{′}}^{*} ( {r}_{o} , z ) \cdot {E}_{{m}_{r} , 0 , {m}_{z}} ( {r}_{o} , z )}{\int ⅆ z {E}_{{m}^{′}}^{*} ( {r}_{o} , z ) \cdot {E}_{{m}^{′}} ( {r}_{o} , z )} .$$

Unless the cavity region with r≦rₒ is precisely identical to the cavity region with r>rₒ (for example, mesa thickness Δt is reduced to zero), there will not exist perfect overlap between the longitudinal modes inside the mesa region and those outside the mesa region 150. In such cases scattering occurs, so that a longitudinal mode confined inside the mesa layer 150 region r≦rₒ and characterized by mode number m will couple to all longitudinal modes outside the mesa layer 150 in region r>rₒ with weights set by the values of c_{m′}. However, in the case that there is in minimal change in the longitudinal mode distribution outside the mesa layer 150 (cavity regions for r>r₀ nearly identical to those cavity regions with r≦r₀) the coupling of the mode Eₘ_{ᵣ}_{,0,m}_{_{z}}(r≦rₒ,z) will be predominantly weighted to the coupling of a preferred longitudinal mode in region r>rₒ with nearly the same longitudinal mode profile, while coupling to other modes in region r>rₒ can be made small. Accurate longitudinal mode matching (nearly identical cavities in r≦r₀ and r>r₀) is thus a key feature for forming low loss optical confinement in VCSEL cavities.

When this condition is satisfied, and when the longitudinal wavevector (z component) of the wavevector in region r>rₒ relative to that of its nearly matched longitudinal mode in region r≦rₒ, the mesa can produce mode confinement with very low optical loss with the eigenmode lateral profile in the region r>rₒ nearly evanescent. In this case, with minimal change in the longitudinal mode distribution so that ∫dzE_{m′}*(rₒ,z)·Eₘ_{ᵣ}_{,0,m}_{_{z}}(rₒ,z)≈0 unless m′_{z}=m_{z}, the wavevector component in the lateral direction outside the mesa layer 150 is set by condition {square root over (kₘ_{ᵣ}²+kₘ_{_{z}}²)}={square root over (k_{m′}_{ᵣ}²+k_{m′}_{_{z}}²)}. In the case that k_{m′}_{_{z}}²>kₘ_{_{z}}², there exists a range of kₘ_{ᵣ}² (inside the mesa region, r≦rₒ) for which k_{m′}_{ᵣ}²<0, or k_{m′}_{ᵣ} (outside the mesa region, r>rₒ) is imaginary. Both of these conditions must be satisfied in a low optical loss VCSEL design. Specifically, the design requires ∫dzE_{m′}*(rₒ,z)·Eₘ_{ᵣ}_{,0,m}_{_{z}}(rₒ,z)≈0 unless m′_{z}=m_{z}and k_{m′}_{ᵣ}²<0 due to k_{m′}_{_{z}}²>kₘ_{_{z}}², to form low loss optical modes confined by an intracavity mesa layer 150. This requires careful placement of electrodes and design of the mesa layer 150 so as to maintain ∫dzE_{m′}*(rₒ,z)·Eₘ_{ᵣ}_{,0,m}_{_{z}}(rₒ,z)≈0 unless m′_{z}=m_{z}, as well as cavity regions immediately adjacent to the mesa and substantially within the optical mode intensity profile. This requirement means that if electrodes are placed above the cavity region 160 to apply a voltage bias to device, and therefore become a boundary condition to the confined mesa mode, the electrode should also be placed above the region 170 that contains the longitudinal resonance shift to cause as little change in the longitudinal mode profile as possible beyond that desired for mode confinement. And the vertical cavity inside the region 160 should also be designed to match as closely as possible the vertical cavity in region 170, except to create the desired shift in the longitudinal resonance. This close matching is most important for the VCSEL cavity regions with the highest mode intensities, i.e. close to the active materials. However, since the VCSEL is highly sensitive to optical loss and generally operates with mirror reflectivities greater than 99%, the mode matching should ideally be satisfied along the entire length of the cavity, except for the mesa layer 150.

Now we further discuss how modes in the region r>rₒ influence the optical loss through coupling to the desired mesa confined mode. We use the Gramm-Schmidt orthogonalization approach to arrive at the collection of m′_{z} modes for r>rₒ assuming that the modes are separable in the r and z directions, and where the desired VCSEL mode is confined by the mesa. This assumption of separability is nearly satisfied by the VCSEL boundary conditions. Modes defined in the region r>rₒ for which k_{m′}_{_{z}}²>kₘ_{_{z}}² lead to imaginary k_{m′}_{ᵣ} and do not propagate away energy from the confined VCSEL mode. However, modes for which k_{m′}_{_{z}}²<kₘ_{₂} do propagate away energy in the lateral direction, since these modes have real k_{m′}_{ᵣ}. These include modes that lie both within the stop-band of the DBR mirrors, and outside the stop-band of the DBR mirrors. The closest matching longitudinal mode profile (in the z-direction) is the mode of the same mode number m′_{z}=m_{z}.

$${\vert {c}_{{m}_{r}^{′} , 0 , {m}_{z}^{′} = {m}_{z}} \vert}^{2} = {\vert \frac{\int ⅆ z {E}_{{m}_{r}^{′} , 0 , {m}_{z}^{′} = {m}_{z}}^{*} ( {r}_{o} , z ) \cdot {E}_{{m}_{r} , 0 , {m}_{z}} ( {r}_{o} , z )}{\int ⅆ z {E}_{{m}_{r}^{′} , 0 , {m}_{z}^{′} = {m}_{z}}^{*} ( {r}_{o} , z ) \cdot {E}_{{m}_{r}^{′} , 0 , {m}_{z}^{′} = {m}_{z}} ( {r}_{o} , z )} \vert}^{2} \leq 1 \qquad ( 1 )$$

where the limit of unity is only obtained when the mesa thickness Δt is reduced to zero. However, normalization requires

$${\sum }_{{m}^{′}}^{} {\vert {c}_{{m}^{′}} \vert}^{2} = 1 ,$$

so that the greater

$${\vert {c}_{{m}_{r}^{′} , 0 , {m}_{z}^{′} = {m}_{z}} \vert}^{2}$$

is less than unity, the greater will be the coupling to modes that propagate energy, including those longitudinal modes that lie outside the stop-band of the DBR mirrors.

To quantify the necessary longitudinal resonance shift to optically confine the mode in the mesa, we use a Bessel function solution to the confined optical mode to relate its longitudinal and transverse wavevectors to its frequency. This frequency must be maintained in the confinement region outside the mesa region as well. This frequency can be expressed as

$$\frac{{ω}_{o}}{c} = \sqrt{\frac{{( 4.81 )}^{2}}{{ɛ}_{r} {W}_{o}^{2}} + {k}_{{m}_{z}}^{2}} = \sqrt{{k}_{{m}_{r}^{′}}^{2} + {k}_{{m}_{z}^{′}}^{2}} \qquad ( 2 )$$

where Wₒ is the mode diameter, approximately set by 2r₀, and εᵣ is an average refractive index in the VCSEL cavity. For the optical mode to be confined, k_{m′}_{ᵣ} must be imaginary. The relationship of (2) therefore gives a minimum mode diameter that can be confined by a longitudinal resonance shift, given by

$${W}_{o} \geq \frac{4.81}{\sqrt{{ɛ}_{r}}} \frac{1}{\sqrt{{k}_{{m}_{z}^{′}}^{2} - {k}_{{m}_{z}}^{2}}} \qquad ( 3 )$$

which sets a minimum optical mode size, and therefore mesa layer 150 diameter 2rₒ, given a designed longitudinal resonance shift. As an example, in a GaAs/AlAs VCSEL with high reflectivity mirrors and designed to operate at ˜0.98 μm wavelength, and assuming an average refractive index of \sqrt{Εᵣ}=3.3 and an etch step of 66 Å placed in the first GaAs layer of the AlAs/GaAs DBR, gives a resonance shift in the longitudinal wavevector components of 4.9×10⁴ m⁻¹, and a minimum mode diameter of Wₒ˜2.5 μm. Mesa layer 150 diameters 2r₀ greater than this will therefore lead to strong optical mode confinement. For example, a mesa layer 150 size of 2r₀˜6 μm diameter will stabilize the optical mode against thermal variations in the VCSEL's refractive index, and show low diffraction loss due to the mesa confinement. The scattering loss will also be low, with a calculated

$${\vert {c}_{{m}_{r}^{′} , 0 , {m}_{z}^{′} = {m}_{z}} \vert}^{2} = 0.997 ,$$

which results in very good overlap between the longitudinal field distributions inside and outside the mesa. A larger mesa layer 150, greater than 10 μm diameter or so, can be used to generate highly multimode operation for multimode fiber applications. The small etch step of layer 150 (for example ˜66 Å) is easily grown over using molecular beam epitaxy or metal organic chemical vapor deposition, and represents a small fraction of the total GaAs quarter-wave thickness of 700 Å. As known by those skilled in the art, these dimensions will scale with the desired emission wavelength and material refractive index.

Although the above example considered a cylindrically symmetric mesa layer 150, similar arguments are understood to cover a noncylindrically symmetric mesa layers 150 such as rectangular, elliptical, or other desirable shapes that may lead to advantages in the radiation pattern or polarization of the lasing mode. It is an advantage of the VCSELs described here that the intracavity mesa layer 150 can be used to achieve very low optical loss, due to optimal longitudinal mode matching between the optical mode region within the cavity region 160 and the optically active region 170 immediately outside the mesa, while maintaining an all-epitaxial or nearly all-epitaxial cavity. The techniques described here can also be applied to cavities that use semiconductor-air DBRs so as to achieve very high mirror contrast, or achieve tenability of the semiconductor-air mirror due to applied electrostatic forces.

In addition, the numbers presented above describe an AlGaAs VCSEL operating at 0.98 μm. An intracavity mesa can also be used in other material systems, scaled in accordance with the optical wavelength and material refractive index. These material systems can include AlGaAs VCSELs operating at other wavelengths, InP-based VCSELs, nitride based VCSELs, and much longer wavelength VCSELs in the near and mid-infrared wavelength ranges.

### EXAMPLE 2

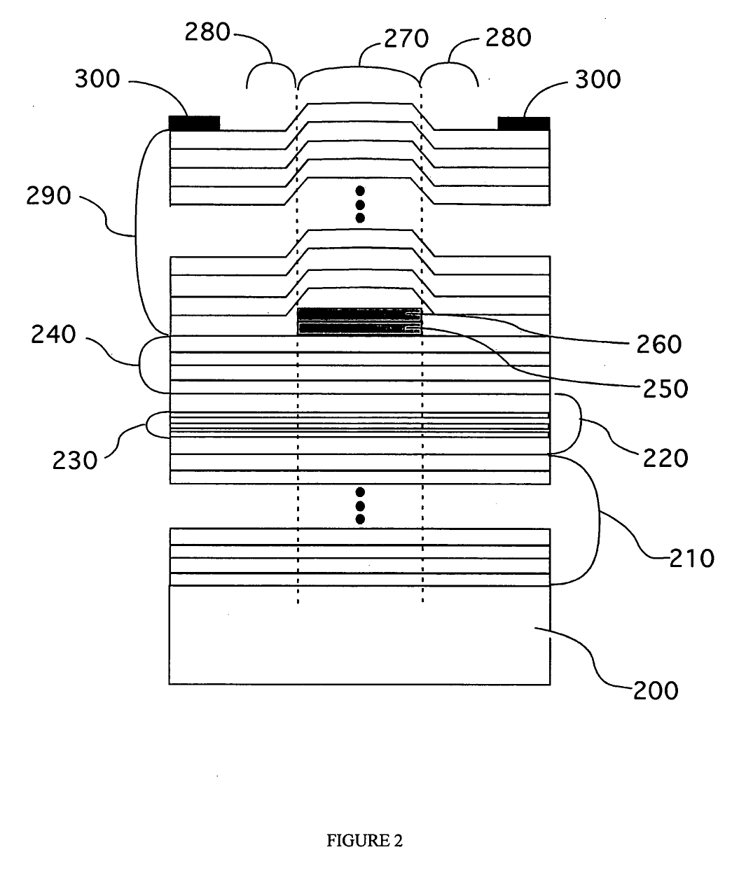

FIG. 2 shows an embodiment used to confine electrical current to the same epitaxial mesa that confines the optical mode based on a tunnel junction. Layer 200 is a substrate receiving epitaxial crystal growth, on which may also be initially deposited buffer layers for surface smoothing and preparation. Layer 210 is a lower DBR mirror with at least the upper portion closest to layers 220 containing impurity doping to make it electrically conductive. Typically, for AlGaAs VCSELs it is desirable to dope these upper layers n-type with Si, Se, or other n-type impurities. The active layer 220, and a portion of the upper mirror 240 and the mesa forming layers 250 and 260 can be grown in the same growth step. Assuming the upper part of the lower mirror, layers 210 are doped n-type, the upper mirror layers 240 are doped p-type using impurities such as C, Be, Zn, Mg, or others, to form a p-n junction for electron and hole injection into the active layers 220. These electrons and holes are then captured in the active region 230 to generate optical gain. In the embodiment of FIG. 2, an n⁺/p⁺ tunnel junction is epitaxially grown in layers 250 and 260 to confine electrical current to the mesa. The confinement of electrical current to the mesa is accomplished by covering the mesa in the second crystal growth step with mirror layers that are doped n-type, at least in the region immediately adjacent to the mesa layer 260 and the upper layer of 240 in the region 290. Using n-type conductivity in these layers forms a low resistance electrical path through the mesa layers 250 and 260, due to the n⁺/p⁺ tunnel junction, and a very high resistance path outside the mesa due to the formation of a lower doped reverse biased n-p junction between layers 240 and 290. This type of tunnel junction is very effective in confining electrical current to precisely the same region that provides optical confinement to the VCSEL lasing mode. The cavity region 270 is formed vertically with the mesa layers 250 and 260, while the cavity region 280 clads the mesa and confines the optical mode. Electrode layers 300 are formed outside the mode confining region 280. The VCSEL could also be designed so that the electrode 300 covers both regions 270 and 280 and serves as part of the upper reflector.

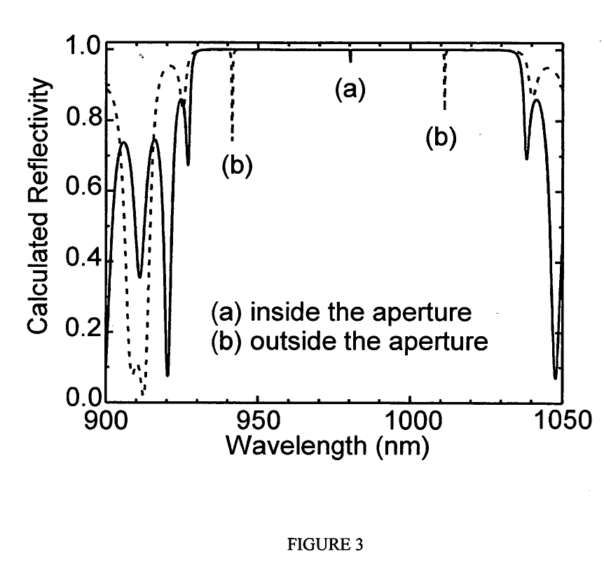

FIG. 3 shows the calculated reflectivities that would occur for plane waves impinging on planar cavities as illustrated by the regions 270 and 280 of FIG. 2. The specific layer structure used for the calculations to form region 270 (above the mesa) are 30 pairs of GaAs/AlAs layers in the lower DBR mirror, with each layer being an optical quarter wave thick, a cavity spacer of Al_{0.15}Ga_{0.85}As that is a full optical wave in thickness, and an initial DBR mirror above the spacer that includes four pairs of optically quarter wave thicknesses of AlAs/GaAs, followed by a less than quarter wave GaAs layer to form the mesa which is selectively removed in region 280. A second growth of layers 290 is assumed to complete the cavity regions 270 and 280. The second growth completes the upper GaAs layer of the first growth to give an optically quarter wave thickness, and adds fifteen additional AlAs/GaAs quarter wave pairs to give a total upper mirror pair number of nineteen. The cavity resonance that results in region 270 containing the mesa occurs at 980 nm, as shown by the solid curve and the resonance just above the (a) in FIG. 3. The cavity resonance that occurs in region 280 is blue-shifted due to the removal of the GaAs layer in this region and occurs at 942 nm as shown by the dashed curve in FIG. 3 just above the (b). A second resonance is also shifted into the stop-band of the DBR mirrors and occurs at a longer wavelength 1011 nm, marked with a second (b) in FIG. 3. The second resonance occurs because of the mode number of the cavity, which does not operate in the lowest order fundamental mode because of the field penetration into the DBRs. In other words, the longitudinal field distribution of the mode of the blue-shifted resonance at 942 nm in cavity region 280 of FIG. 2 most closely matches the longitudinal field distribution of the resonance in region 270 at 980 nm, and is responsible for the optical confinement of the mode in the mesa region 270. The longitudinal field distribution of the mode at 1011 nm in region 280 has a different order number, and can cause scattering loss. In this particular example, the step height has been increased to accommodate the tunnel junction in mesa layers 250 and 260, but at the penalty of increasing the optical scattering loss. This scattering loss can be reduced by reducing the layer thicknesses of 250 and 260 so that cavity region 270 more closely matches cavity region 280 to reduce the VCSEL's threshold.

The mesa based on a tunnel junction current confinement as shown in FIG. 2 is demonstrated experimentally using molecular beam epitaxy and standard device fabrication techniques. The epitaxial growths are performed on an n-type GaAs substrate using molecular beam epitaxy. The bottom DBR consists of thirty pairs of n-doped GaAs/AlAs quarter wave layers. Three 6-nm-thick In_{0.2}Ga_{0.8}As quantum wells are placed at the center of the undoped full-wave cavity spacer and separated by 10 nm GaAs barriers. A partial p-type top DBR mirror of four Al_{0.7}Ga_{0.3}As/GaAs pairs is grown above cavity followed by the tunnel junction which consists of, from bottom to top, 10 nm p-type (Be=5×10¹⁷ cm⁻³) Al_{0.7}Ga_{0.3}As etch stopper, 30 nm p⁺ (Be=5×10¹⁹ cm⁻³) GaAs, 10 nm n⁺ (Si=1×10¹⁹ cm⁻³) In_{0.1}Ga_{0.9}As, and 30 nm n⁺ (Si=1×10¹⁹ cm⁻³) GaAs. Photolithography and wet etching are used to define a mesa by selectively etching the tunnel junction layers outside a shallow mesa, with the mesa diameter ranging from 6 to 10 μm diameter. A subsequent epitaxial overgrowth of fifteen pairs of n-doped GaAs/AlAs DBRs is then performed that preserves the shallow mesa step height. A metal contact ring is deposited concentric with regrowth-defined mesa region, and 140 μm mesas are deeply etched for device isolation. 140 μm deeply etched mesas and metal contacts are also made on the same wafer, but that do not include the mesa, to test the current blocking regions outside the mesa.

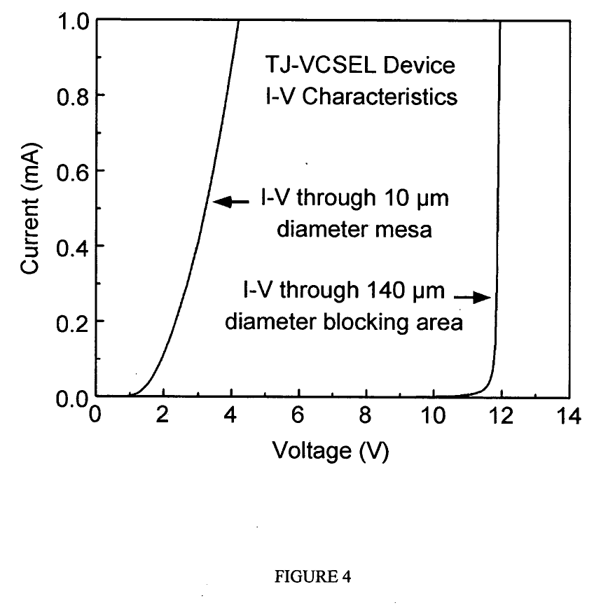

Current-voltage curves are measured for region 270 of FIG. 2 using a 10 μm diameter mesa, and compared with current voltage characteristics measured through the blocking regions 280 of FIG. 2 outside the mesa. The diameter used for the current voltage characteristic outside the mesa in region 280 is 140 μm. The current-voltage characteristics measured across both regions are shown in FIG. 4 and confirm that current is effectively confined to the mesa. FIG. 4 shows that even for voltages as high as 11 V little current is passed through the blocking layers outside the mesa. In comparison the 10 μm diameter mesa region passes current at just over 1 V forward bias, which is the turn-on voltage of the p-n junction used to inject electrons and holes into layers 220 of FIG. 2 (the active region). Therefore the electrical current is confined to pass through the mesa layers 250 and 260, that also confine the optical mode.

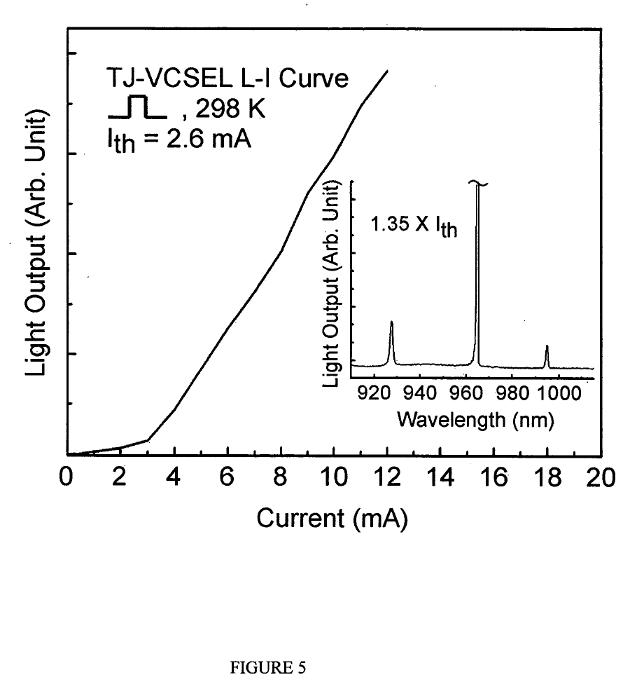

The VCSEL is tested under room temperature operation, and the pulsed light-current characteristic of a 10 μm device is shown in FIG. 5. The VCSEL has a pulsed lasing threshold of 2.6 mA. The lasing spectral characteristics of the VCSEL are shown in the inset of FIG. 5. Some current spreading occurs below the mesa of the VCSEL to excite emission in region 280 outside the mesa cavity region 270. This current spreading can be further controlled by placing the mesa closer to the active layers 220 of FIG. 2, and reducing the vertical resistance through the p-type DBR by using C doping instead of Be doping. However, for this first demonstration the spectrum created by the current spreading reveals the optical modes of both the region 270 of the mesa of FIG. 2, and outside the mesa in region 280 of FIG. 2, demonstrating the two distinct cavity regions. Lasing occurs only within the mesa region 270 on its mode at 965 nm. The two additional peaks at 927 and 995 nm show the cavity resonances in region 280, with the cavity resonance at 927 nm serving to confine the optical mode to region 270. Therefore the mesa, formed by the shallow surface etch and covered by a subsequent epitaxial growth of a DBR mirror, yields a high quality mode confined VCSEL.

### EXAMPLE 3

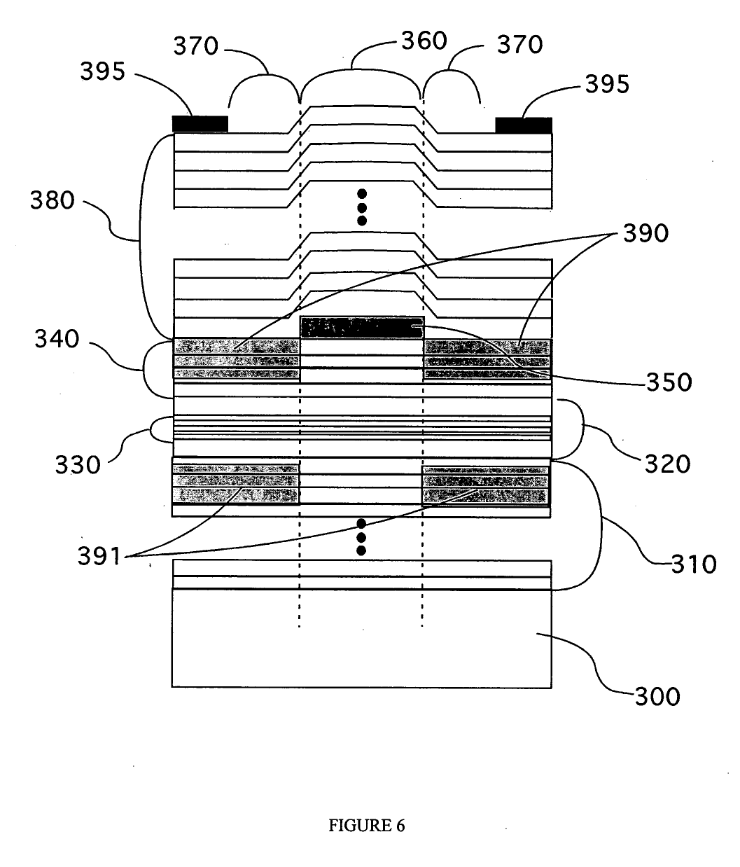

Referring to FIG. 6, a lower semiconductor DBR consisting of layers 310 is grown on substrate 300, that may include additional buffer layers, followed by an active region 320 containing active layers 330 that confine electron and hole charge carriers. The upper DBR includes layers 340, with a pair number that may vary from zero or greater, and a mesa layer 350. Following epitaxial growth impurities are introduced into the upper cavity region layers 340 to form the crystal regions 390, using either diffusion or implantation, while masking the mesa layer 350 and the crystal region beneath it from the impurities. In this embodiment at least the upper region of the lower DBR layers 310 adjacent to the active region 320 are doped with n-type impurities grown into the crystal, while the upper layers 340 and mesa forming layer 350 are doped p-type. The selective introduction of impurities outside the mesa layer 350 can be performed using diffusion or implantation with the same masking material used to form the mesa 350. The introduction of the impurities is used to render the material outside the mesa highly resistive to current flow, and the use of one masking step to both selectively introduce the impurities and form the mesa results in a self-aligned process. The impurities are chosen with type and concentration to cause current flow through the device to be directed through the mesa region 360. This can be accomplished by introducing impurities that form deep levels, such as protons, oxygen, or heavy metals. Or, if subsequent higher temperature process steps are required that sufficiently anneal the crystal defects, shallow donor impurities, such as through Si diffusion or implantation, can be used to convert the crystal to n-type in the shaded regions of layers 340. Sufficient donor impurities must be introduced to partially convert the layers of 340 to n-type outside the mesa region 350, while retaining a reverse-biased p-n junction between the upper converted layers 340 and the lower layers of 340 adjacent to the active region 320. A second epitaxial growth step is then used to the mesa layer 350 with p-type semiconductor, thus forming a conducting channel through the mesa region 350 forming the cavity region 360 that is again aligned to the optical mode confined by region 370. In this and other embodiments the conductivity types may be changed to realize in essence the same device, with the upper layers of the lower mirror 310 doped p-type, the lower layers 340 and mesa initially doped n-type, the upper layers of 340 selectively converted to p-type, and n-type semiconductor layers 380 deposited over the crystal surface in a second growth step. An additional implant of impurities may also be performed to create a second reverse biased p-n junction region 391 in the lower mirror layers of 310. This second reverse biased p-n junction can lead to more effective current confinement and lower capacitance through the introduction of the second reverse-biased p-n junction, and therefore lower threshold and high modulation speed. For the doping types considered above, region 391 should be formed p-type through implantation of Be, Zn, Mg, C, or a similar acceptor impurity. Electrodes 395 are formed outside the cavity regions 360 and 350, or alternatively may be designed as part of the optical cavity to continuously cover these regions as in FIG. 1C.

### EXAMPLE 4

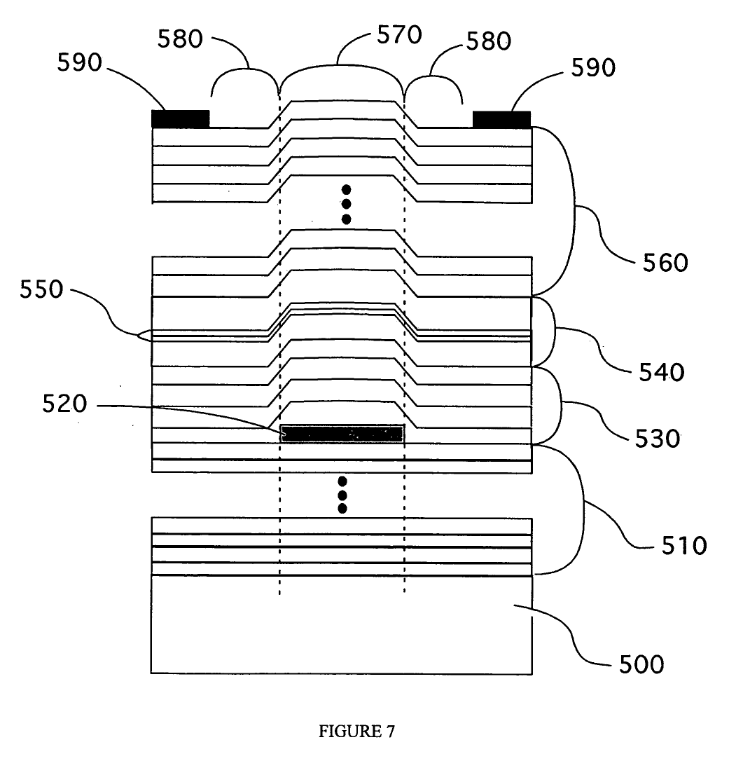

Referring now to FIG. 7, we describe a means for forming the mesa in the lower part of the cavity, again to obtain optical confinement and current confinement to the same active area. In FIG. 7 the mesa forming layer 520 is epitaxially grown on the lower DBR layers 510, which is also grown on substrate 500 that may contain addition buffer and crystal smoothing layers. The mesa forming layer 520 is again patterned using etching of the crystal surface. An additional growth step as illustrated is then performed on the crystal surface to cover the mesa layer 520 and exposed surface of 510 with an additional number of layers 530, which maybe zero or greater, followed by the active region 540 containing electron and hole confining layers 550, and upper mirror layers 560. A potential benefit of this approach is that the active material not above the mesa forming layer 520 may have a reduced interaction with the optical mode confined by the mesa, due to its vertical shift away from an antinode position in the cavity. Cavity regions 570 correspond to either the region of the mesa 520, or region 580 just outside the mesa with a resonance shift used to confine the optical mode to the mesa region 570. Electrodes 590 are formed outside the mode confining region 580.

Current confinement can be obtained to the cavity region 570 using similar schemes to when the mesa is formed above the active region. A tunnel junction can be grown into the mesa layer 520, or an implant or impurity diffusion can be performed into the DBR layers of 510 outside the mesa layer 520.

### EXAMPLE 5

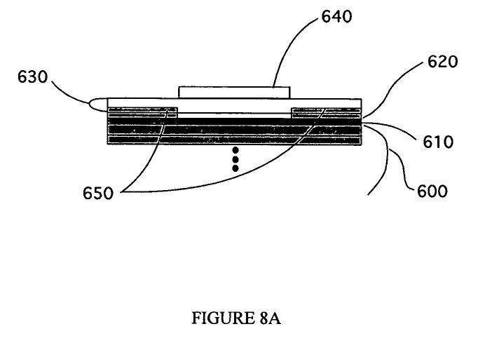

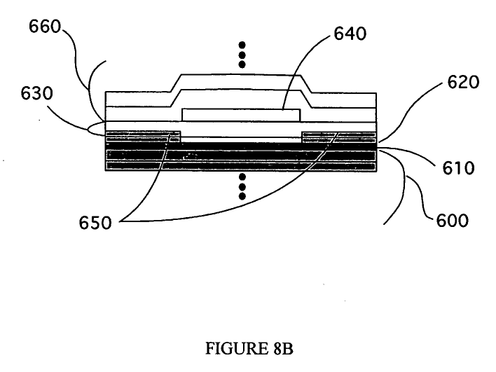

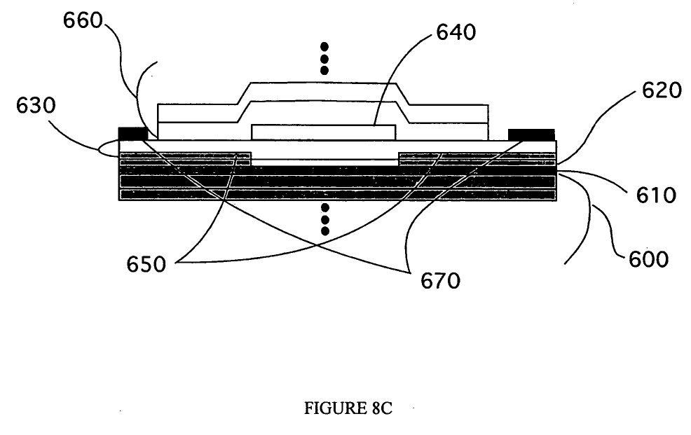

Referring to FIG. 8A, in another embodiment the tunnel junction layers of opposite conductivity type, layers 610 and 620, that will be used to form the mesa is formed below the mesa forming layers. In FIG. 8A layers 600 and 610 have one conductivity type, with 610 being heavily doped and layers 600 being more light doped, and layers 620, 630, and 640 have the opposite conductivity type. Impurities are then diffused or implanted into regions 650 to convert the conductivity type in all or part of layers 630 to the same conductivity type as 610 and 600. In this way current confined to the mesa region 640 due to reverse biased p-n junctions that exist outside the mesa, and away from the heavily doped tunnel junction. Referring to FIG. 8B, the etched mesa is then overgrown with semiconductor layers 660 of the same conductivity type as the mesa layer 640.

Referring to FIG. 8C, in another embodiment the current is directed around the mesa by making electrical contact through electrodes 670 applied to the surface of layers 630. This can be accomplished using a relatively deep implantation that converts the semiconductor material above the tunnel junction to the same conductivity as layers 600 below the tunnel junction, but leaving the upper surface of layers 630 the same conductivity type as the overgrown material layers 650. The overgrown semiconductor DBR, layers 660, can then be left undoped. In this scheme current is confined to the mode confined region only below the mesa, by first routing laterally along the crystal surface of layers 630, and then through the tunnel junction in under the mesa layer 640. This embodiment can be desirable in obtaining very low optical loss in the semiconductor DBRs by removing doping from most of the cavity.

Generally, the mesa can be placed at various locations in the cavity, either close to the active region are further away, as well as at antinodes or away from the antinodes of the standing field, to alter its impact in the resonance shift between the cavity regions inside and outside the mesa regions. The impact of the mesa step can be calculated and determined using the plane wave (or longitudinal) mode transmission or reflectivity characteristics as illustrated in FIG. 3 to determine the amount of mode confinement. Care must be exercised to compare that longitudinal mode outside the mesa region intended for optical confinement has the same mode number, or nearly the same longitudinal field profile, as the lasing mode confined by the mesa. The largest mode confinement for a given mesa thickness Δt is obtained by placing the mesa closer to the center of the cavity, where the mode intensity is highest. By placing the mesa closer to the cavity center the actual thickness of the mesa, Δt, may be reduced making a subsequent crystal growth step easier to obtain low optical loss.

The choice of the mesa layer material and the subsequent epitaxial growth step that covers the mesa are critical features in obtaining high optical quality in the cavity and low electrical resistance. Excellent optical quality material can generally be obtained with non-Al bearing materials in the epitaxial surface to be overgrown. For VCSELs grown on GaAs substrates, the top surface of the mesa can be GaAs, as can the top layers of the crystal surface in the regions where the mesa layer is removed, for example for the upper layers of 510 and 520 in FIG. 7. In some cases InGaP nominally lattice-matched to GaAs may be desirable as the top layers since interface defects between subsequent growths are lower, and lower electrical resistance can be obtained in such regrown interfaces. The mesa layer itself, for example 520 in FIG. 7 or 150 in FIG. 1A, may be a layered heterostructure even containing AlGaAs, and the small regions exposed during the etching of the mesa layers have not proved to be problematic in the epitaxial regrowth. Thin strained layers of InGaAs used at the surface of the mesa layer, either 520 in FIG. 7 or 150 in FIG. 1A, may also be desirable for their reduced number of surface defects that lead to interface states.

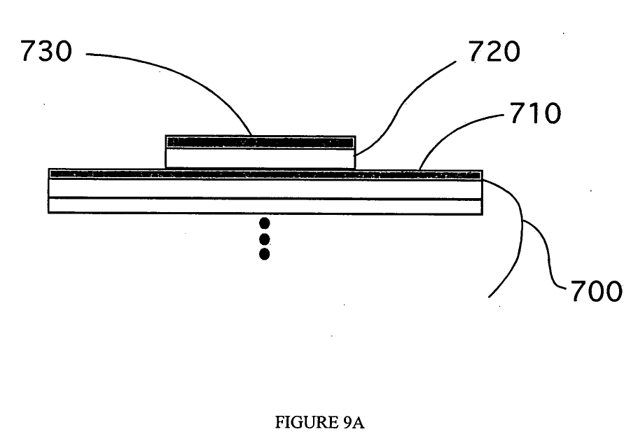

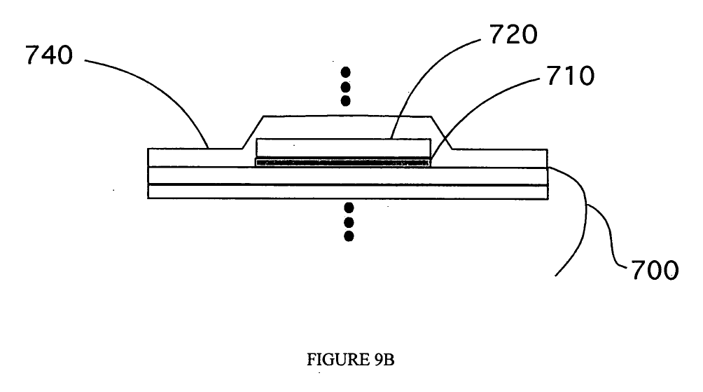

In some cases, however, it may be desirable to obtain the subsequent regrowth directly on AlGaAs material either on top of the mesa or outside the mesa. FIG. 9A depicts an embodiment that allows for this regrowth. The mesa layer is then formed from AlGaAs 720 and GaAs layer 730, with the upper layer beneath the mesa terminated by GaAs layer 710 covering layers 700. The mesa layers are patterned using lithography and etching to leave the structure shown in FIG. 9A. This epitaxial structure is returned to the growth chamber and an in-situ thermal etch is performed to selectively remove GaAs layer 730 and the GaAs layer 710 outside the mesa, so that AlGaAs now remains at the crystal surface. While in the growth chamber the subsequent epitaxial growth of layers 740 is performed to cover the remaining mesa layer 720 and surface layers 700 outside the mesa. Of course 720 can also be made up of heterolayers.

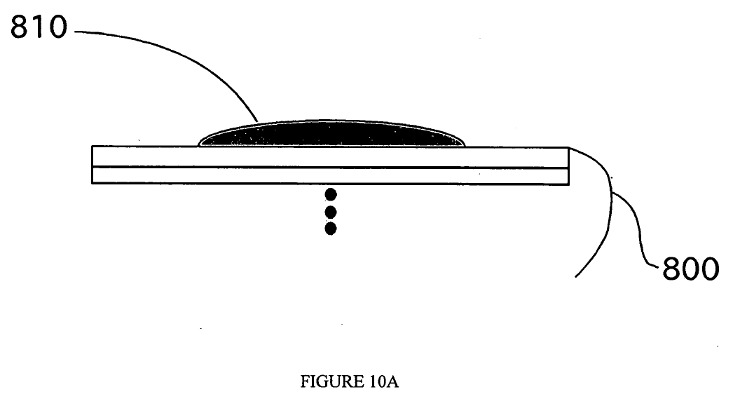

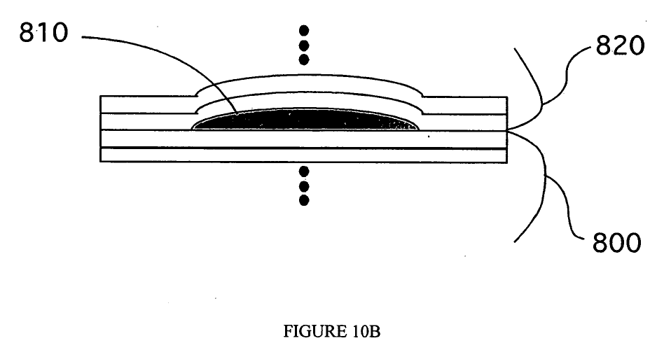

In another embodiment of forming the mesa, shown in FIG. 10A and 10B, the lateral profile of the mesa itself can be controlled to form a lens from the graded thickness of the mesa. This can be effective in reducing optical scattering loss that may occur at the edge of the cavity. In this embodiment the graded thickness can be formed by melting a photoresist pattern in a thermal cycle to obtain a curved profile in the photoresist, and transferring this pattern to the semiconductor surface to form the mesa layer 810 on layers 800. This graded thickness mesa is then again covered by a subsequent semiconductor growth that includes DBR layers 820. In such a device it may be desirable to use an implantation process to obtain the current blocking regions, and avoid passing current directly through the mesa. It may also be desirable to use a tunnel junction below the graded mesa, as illustrated in FIGS. 8A, and 8B or 8C.

### EXAMPLE 6

So far the examples presented have considered the intracavity mesa as being placed either in an upper semiconductor DBR, or a lower semiconductor DBR of the VCSEL. In another embodiment the mesa layer can be placed within the cavity spacer regions, for example within layers 120 of FIGS. 1A, 1B, or 1C. Calculations show that placement of the mesa within the cavity spacer region results in a smaller mesa height, Δt, to achieve the same mode confinement as compared to placing the mesa within the mirrors. The reason is that the layer thickness shift between cavity regions 160 and 170 occurs in a higher intensity region of the lasing mode. While the placement of the mesa in the higher intensity region of the lasing mode increases the optical confinement reducing the diffraction loss, the smaller step height leads to better mode matching and less optical scattering loss.

### EXAMPLE 7

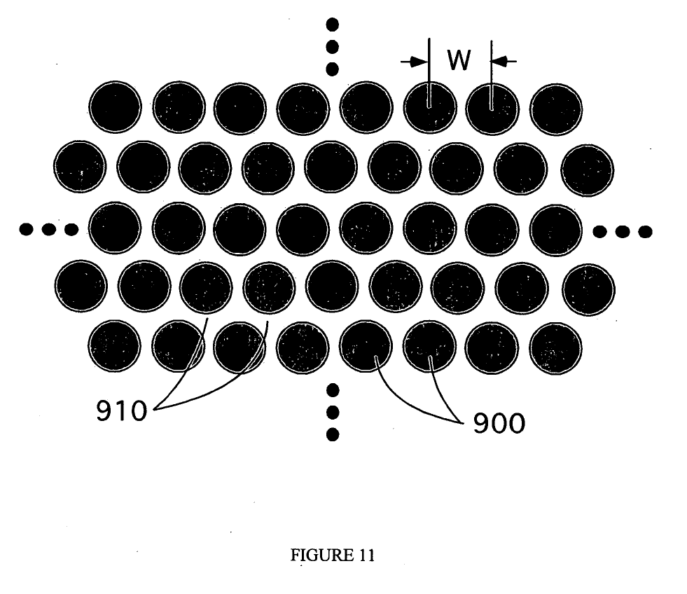

The intracavity mesa provides a convenient means to arrange VCSELs into arrays of various densities, either for individual addressing elements of the array or for parallel addressing the entire array. In such an array as illustrated in FIG. 11, the mesas 900 can be arranged with spacing between them of regions 910, to either obtain optical coupling between the elements or with wide enough separation so that they operate uncoupled. Of particular interest is when the mesas are reduced in size and their center-to-center spacings, the distance w of FIG. 11, are sufficiently small that they approach optical wavelength dimensions. In such a case when the periodicity of the distance w becomes on the order of an integer multiple of one-half the optical wavelength in the material, a photonic crystal can be formed that inhibits mode propagation in the lateral dimension. This effect happens not only with a square lattice as illustrated in FIG. 11, but also with other lattice types with sufficiently small spatial periodicities. Such a two dimensional photonic crystal in the lateral direction can force the transverse k-vector in the VCSEL plane to nearly zero, resulting in a lowest order fundamental mode of the crystal. This lowest order mode can then exist over a larger mode area than with a single mesa. Therefore, in another embodiment the mesas are arranged into an array, and the spacings of the array are reduced to a microarray that forms a two-dimensional photonic crystal in the plane of the epitaxial growth. In FIG. 11 a triangular lattice of the two-dimensional photonic crystal is shown, but a square—or other lattice patterns are also possible.

1. A semiconductor vertical cavity surface emitting laser comprising:
a mode confining region having a first longitudinal dimension; and
a mode confined region within the mode confining region having a second longitudinal dimension which is greater than the first longitudinal dimension, wherein at least one of the mode confining region and the mode confined region are configured to laterally confine an optical mode of the laser,
wherein the mode confined region is a mesa-formed region containing a mesa adjacent an epitaxial mirror, at least a portion of which is electrically conductive.

2. The laser of claim 1, wherein the mesa provides a step height between the mode confined region and the mode confining region.

3. The laser of claim 2, wherein the step height is less than a quarter of an optical wavelength.

4. The laser of claim 1, wherein the mode confining region is configured to convert a transverse portion of the optical mode to nearly evanescent waves outside the mode confined region.

5. The laser of claim 1, wherein the mode confined region includes multiple mesas arranged in a micro-array.

6. The laser of claim 1, wherein at least one of the mode confining region and the mode confined region are configured to laterally confine electric current.

7. The laser of claim 6, wherein the electric current is confined through use of a tunnel junction in or below the mesa.

8. The laser of claim 1, wherein the mode confining and mode confined regions are between upper and lower reflection regions.

9. The laser of claim 8, wherein at least one reflection region includes epitaxial distributed Bragg reflecting (DBR) mirrors.

10. The laser of claim 8, wherein at least one reflection region is augmented with one or more dielectric layers to increase its reflectivity.

11. The laser of claim 8, wherein at least one reflection region is augmented with one or more metal layers to increase its reflectivity.

12. The laser of claim 8, wherein the mesa is formed in the upper reflection region.

13. An epitaxial semiconductor vertical cavity surface emitting laser comprising:
a first vertical cavity and a second vertical cavity, each vertical cavity having a respective longitudinal cavity length;
wherein
the first vertical cavity and the second vertical cavity are both between an upper reflection region and a lower reflection region;
the first vertical cavity is within the second vertical cavity;
the first vertical cavity includes a mesa region such that the longitudinal cavity length of the first vertical cavity is longer than the longitudinal cavity length of the second vertical cavity; and
except for the mesa, the first vertical cavity has a layer composition that is substantially the same as a layer composition of the second vertical cavity.

14. An epitaxial semiconductor vertical cavity surface emitting laser comprising:
a substrate;
one or more lower mirror layers on the substrate;
an active layer on the one or more lower mirror layers;
one or more upper mirror layers on the active layer;
a mesa located within either the lower mirror layers or the upper mirror layers, wherein the mesa has a lateral dimension that is less than a lateral dimension of the one or more lower mirror layers or the one or more upper mirror layers, respectively; and
wherein the mesa is configured such that a first vertical cavity which includes the mesa has a cavity resonance that is different from a cavity resonance for a second vertical cavity which does not include the mesa and which is adjacent the first vertical cavity; and
except for the mesa, the first vertical cavity has a layer composition that is substantially the same as a layer composition of the second vertical cavity.

15. A method of forming a vertical cavity surface emitting laser, comprising:
epitaxially growing one or more lower mirror layers on a substrate;
epitaxially growing an active layer on the one or more lower mirror layers;
epitaxially growing one or more of a first set of upper mirror layers on the active layer;
forming a mesa on the first set of upper mirror layers; and
epitaxially growing one or more of a second set of upper mirror layers on the mesa and the first set of upper mirror layers;
wherein
the mesa is formed such that a first vertical cavity which includes the mesa has a cavity resonance that is different from a cavity resonance for a second vertical cavity which does not include the mesa and which is adjacent the first vertical cavity; and
except for the mesa, the first vertical cavity has a layer composition that is substantially the same as a layer composition of the second vertical cavity.

16. The method of claim 15, wherein at least one of the mirror layers is formed by the absence of semiconductor material to form one or more semiconductor-air-semiconductor reflections within at least one the first and second vertical cavities.

17. The method of claim 15, including the step of defining the second cavity region using lithography to eliminate external process variations.
